(19) United States
(12) Patent Application Publication
(10) Pub. No.: US 2004/0009680 A1
(43) Pub. Date: Jan. 15, 2004

(54) Seedless method of forming a silicon germanium layer on a gate dielectric layer

(75) Inventors: Lee Luo, Fremont, CA (US); Shulin Wang, Campbell, CA (US); Li Fu, Santa Clara, CA (US); Xianzhi Tao, Palo Alto, CA (US); Kevin L. Cunningham, Mountain View, CA (US)

Correspondence Address: PATENT COUNSEL, APPLIED MATERIALS, INC., Legal Affairs Department, P.O. Box 450A, Santa Clara, CA, 95052, US

(73) Assignee: Applied Materials, Inc.

(21) Appl. No.: 10/192,889

(22) Filed: Jul. 10, 2002

(51) Int. Cl. H01L 21/8238

(52) U.S. Cl. 438/933

(57) ABSTRACT

A silicon germanium layer is deposited directly on a gate dielectric layer formed over a semiconductor material of a substrate. A mixture of germaine and disilane gases is preferably used to form the silicon germanium layer. Disilane, when used together with germaine, forms a uniform silicon germanium layer.

### BACKGROUND OF THE INVENTION

1). Field of the Invention

This invention relates generally to a semiconductor processing method, and more specifically to the manufacture of a gate electrode of a semiconductor transistor.

2). Discussion of Related Art

Integrated circuits are usually manufactured in and on silicon and other semiconductor wafer substrates. An integrated circuit of this kind may have literally millions of interconnected metal-oxide-silicon (MOS) transistors. Such a transistor typically has a gate dielectric layer that is formed on the semiconductor material of the substrate, and a gate electrode on the gate dielectric layer. The gate electrode is usually made of silicon or another semiconductor material. The electrode is doped with a dopant such as boron, phosphorus, or arsenic. The wafer is subsequently heated to activate the dopant and make the electrode conductive.

For better transistor functioning, it is required that the gate dielectric layer be as thin as possible. Thinner gate dielectric layers have more capacitance than do gate dielectric layers which are thicker. If the region of the gate electrode near the gate dielectric layer has few electric current carriers, the effective capacitance of the gate dielectric layer combined with the gate electrode is lower. The depletion of electric current carriers in the gate electrode near the gate dielectric layer is known as “poly depletion” or “carrier depletion” or “polysilicon-gate depletion.” This depletion of electric current carriers in the gate electrode near the gate dielectric layer is discussed in the book entitled Fundamentals of Modern VLSI Devices by Yuan Taur and Tak H. Ning, Cambridge University Press, 1998, ISBN 0-521-55959-6, specifically discussed in Section 2.3.4.2.

International patent application number PCT/US00/31676 discloses the fabrication of an electrode of a transistor, wherein the electrode includes silicon germanium. Silicon germanium is desirable because it has a material characteristic which increases the number of electric current carriers in the material. The material characteristic is known as the “Band Gap,” which is smaller for silicon germanium than it is for polysilicon. The process described in the above international application, however, requires the formation of a polysilicon seed or wetting layer, which increases the effective width of the gate dielectric layer.

### SUMMARY OF THE INVENTION

According to an aspect of the invention, a silicon germanium layer is deposited directly on a gate dielectric layer formed over a semiconductor material of a substrate.

A mixture of germaine and disilane gases is preferably used to form the silicon germanium layer. It is believed that disilane gas is more reactive than silane gas. Disilane gas also has a reactivity which more closely matches germaine than does silane gas. It is believed that these factors contribute to the ability for disilane, when used together with germaine, to form a uniform silicon germanium layer directly on a gate dielectric layer.

### BRIEF DESCRIPTION OF THE DRAWINGS

The invention is further described by way of example with reference to the accompanying drawings, wherein:

FIG. 1 is cross-sectional side view illustrating a semiconductor processing system that is used for carrying out the process according to the invention;

FIG. 2 is an enlarged view of a chamber and internal components of the system;

FIG. 3 is a cross-sectional side view illustrating a wafer substrate having a gate dielectric layer formed thereon before being processed in the system of FIG. 1;

FIG. 4 is a view similar to FIG. 3, after a silicon germanium layer is formed directly on the gate dielectric layer;

FIG. 5 is a table illustrating the process flow for forming the silicon germanium layer;

FIG. 6 is a view similar to FIG. 4, after a cap layer is formed on the silicon germanium layer; and

FIG. 7 is a view similar to FIG. 6, illustrating the manufacture of a transistor out of the layers of FIG. 6.

### DETAILED DESCRIPTION OF THE INVENTION

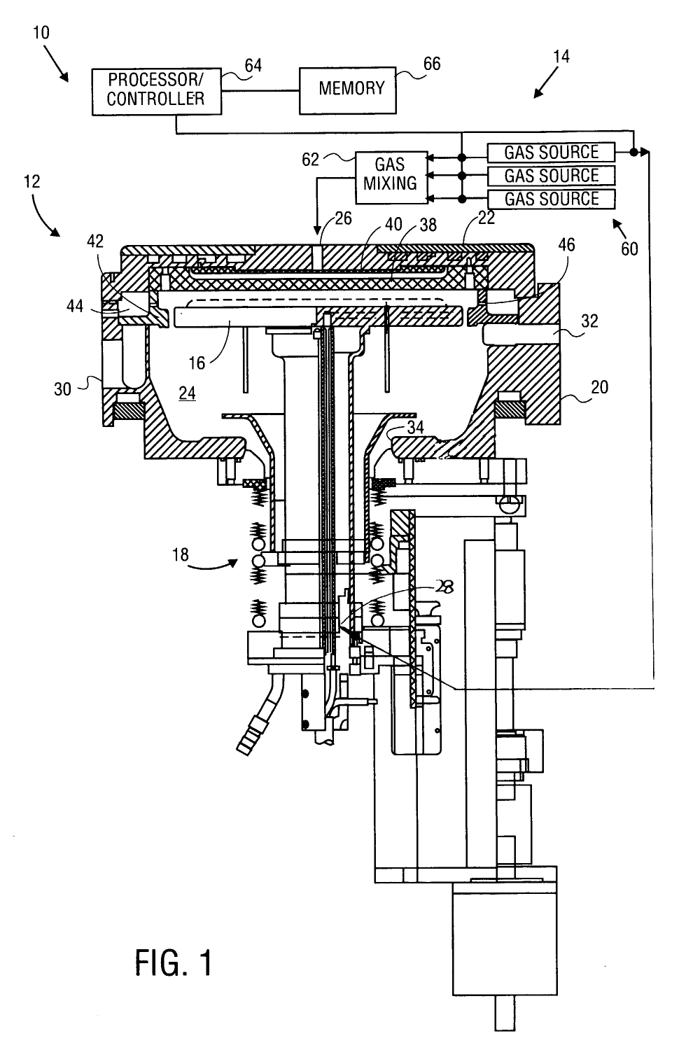

FIG. 1 of the accompanying drawings illustrates a semiconductor processing system 10 that is used for carrying out the method according to the invention. The system 10 includes a low-pressure chemical vapor deposition chamber 12, a gas provision apparatus 14, a susceptor 16, and a susceptor elevating apparatus 18.

The chamber 12 includes a lower body 20 and a lid 22. The lid 22 seals peripherally with an upper extremity of the body 20. The body 20 and the lid 22 jointly define an inner volume 24 of approximately six to seven liters. A first gas inlet port 26 is formed through a center of the lid 22. A second gas inlet port 28 is formed into a base of the susceptor elevating apparatus 18. A gas outlet port 30 is formed in a side of the body 20. The body 20 also has a slit valve opening 32 in one side thereof, and a susceptor elevating apparatus opening 34 in a base thereof.

A gas dispersion plate 38 or “shower head” is mounted below the lid 22. Surfaces of the lid 22 and the gas dispersion plate 38 jointly define a thin horizontal cavity 40. The gas dispersion plate 38 has a multitude of openings (not shown) formed therethrough that place the cavity 40 in communication with the inner volume 24.

A gas accumulation ring (or “pumping plate”) 42 is mounted within the chamber 12. The gas accumulation ring 42, together with surfaces of the chamber 12, define a ring volume 44, with an inner diameter approximately equal to an outer diameter of the inner volume 24. Gas outlet openings 46 are formed at a number of locations around the gas accumulation ring 42, and place the inner volume 24 in communication with the ring volume 44. The ring volume 44 is in communication with the gas outlet port 30.

A gas or gases can flow through the first gas inlet port 26 into the cavity 40. Gas then flows radially within the cavity 40. The gas can then flow through the openings in the gas dispersion plate 38 into the inner volume 24. More gas can enter through the second gas inlet port 28 into the inner volume 24. The gas or gases can exit the inner volume 24 through the gas outlet openings 46, be accumulated in the ring volume 44, and subsequently be pumped out through the gas outlet port 30.

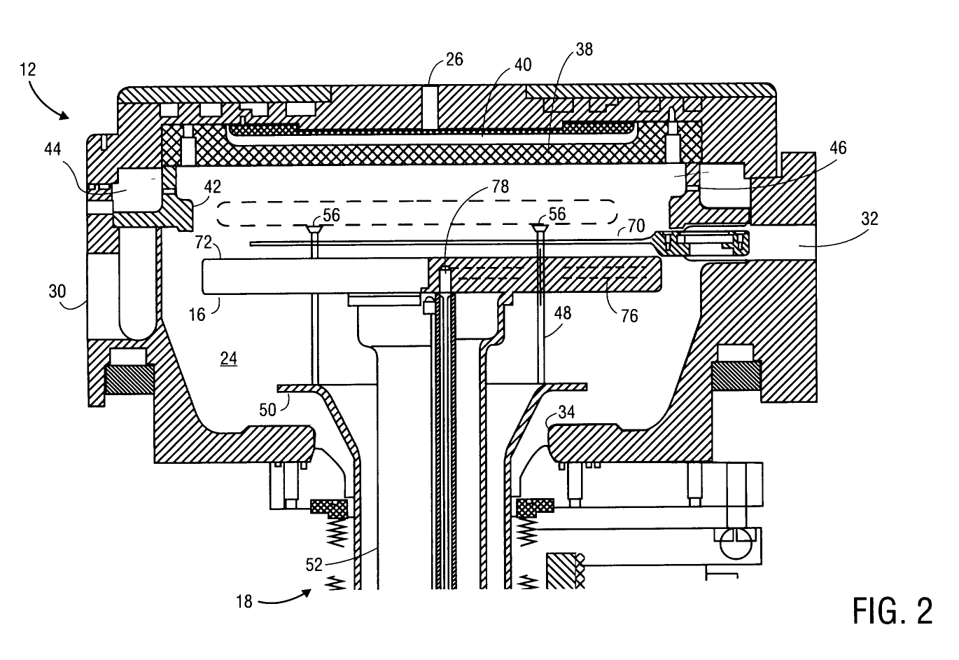

Referring to FIG. 2, the elevating apparatus 18 includes a set of elevating pins 48, a pin elevator 50, and a susceptor elevator 52. The pin elevator 50 and the susceptor elevator 52 are tubular members that extend through the apparatus opening 34 into the inner volume 24. The susceptor elevator 52 is, for the most part, located within the pin elevator 50. A portion of the susceptor elevator 52 extends out of an upper end of the pin elevator 50. The susceptor 16 is mounted to an upper end of the susceptor elevator 52. Vertical movement of the susceptor elevator 52 causes vertical movement of the susceptor 16.

The pins 48 extend through openings (not shown) in the susceptor 16. Each pin 48 has a head 56 at an upper end thereof. The pin elevator 50 engages with lower ends of the pins 48. Vertical movement of the pin elevator 50 causes vertical movement of the pins 48 relative to the chamber 12. The pins 48 also move relative to the susceptor 16, assuming that the susceptor 16 is stationary.

Referring again to FIG. 1, the gas provision apparatus 14 includes a gas bank 60, a gas-mixing manifold 62, a processor/controller 64, and memory 66. The gas bank 60 has number of different gas sources. In the present example, the sources that are used are nitrogen gas (N₂), disilane gas (Si₂H₆), and germaine gas (GeH₄). The gas source is connected through a respective valve to the gas-mixing manifold 62. The gas-mixing manifold 62 is connected to the first gas inlet port 26. The nitrogen source gas is also connected through a valve to the second gas inlet port 28.

The processor/controller 64 is connected to the valves. The processor/controller 64 can operate each valve so as to open or close flow from a respective gas source to either the gas-mixing manifold 62 or to the second gas inlet port 28. The memory 66 is connected to the processor/controller 64. A program can be stored in the memory 66 and be read by the processor/controller 64. The valves can thus be opened or closed according to instructions stored in the memory 66.

Referring to FIG. 2, in use, a wafer substrate is located on a blade 70 and then transported on the blade 70 through the slit valve opening 32 into the inner volume 24. The pin elevator 50 is raised so that the heads 56 make contact with a lower surface of the wafer substrate, and lift the wafer substrate off the blade 70. The blade 70 is then removed through the slit valve opening 32. The susceptor 16 remains stationary throughout this process.

With the pin elevator 50 remaining stationary, the susceptor elevator 52 is then raised. Raising of the susceptor elevator 52 causes movement of the susceptor 16 in a vertically upward direction, while the pins 48 slide along the openings in the susceptor 16. The susceptor 16 is raised until an upper surface 72 thereof makes contact with a lower surface of the wafer substrate. The susceptor 16 is then further elevated until an upper surface of the wafer substrate is at a required distance from the gas dispersion plate 38. In the present example, the upper surface of the wafer substrate is at a distance of approximately 14 mm from the gas dispersion plate 38.

Current is provided to a resistive heater 76 in the susceptor 16. The current heats the resistive heater 76, and heat conducts from the resistive heater 76 through the susceptor 16 to the wafer substrate. A thermocouple 78 is located within the susceptor 16, and provides temperature feedback for purposes of controlling the temperature of the susceptor 16 and, indirectly, the temperature of the wafer substrate. The temperature of the wafer substrate is approximately 20° C. lower than that of the susceptor 16.

All the valves from the gas sources of the gas bank 60 are, at this stage, still closed, and a slit valve closes the slit valve opening 32. A pump connected to the gas outlet port 30 may be operated to reduce the pressure in the inner volume 24. The valves from the gas sources of the gas bank 60 are then selectively opened to allow a desired mix of gases through the inlet ports 26 and 28 into the inner volume 24.

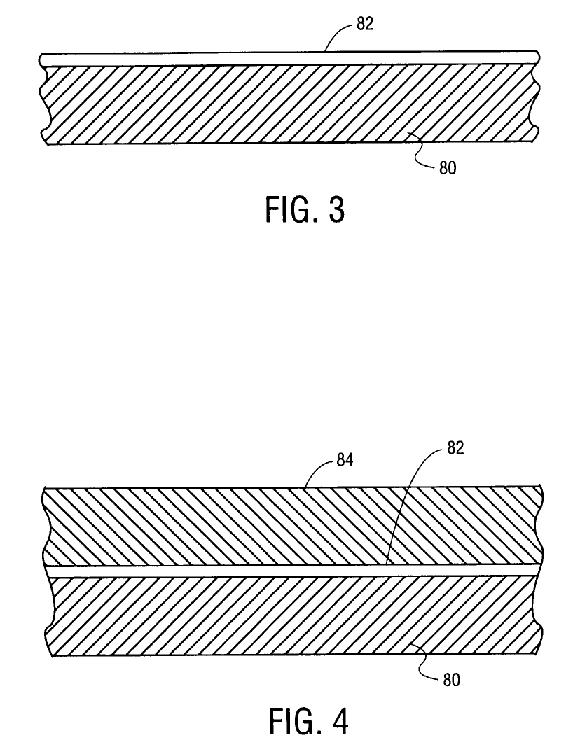

FIG. 3 illustrates a portion of a wafer substrate 80 before being inserted into the chamber 12. The wafer substrate 80 is made of monocrystalline silicon upon which a thin layer of epitaxial silicon is grown. A thin silicon dioxide gate dielectric layer 82 is grown on an upper surface of the epitaxial silicon layer. The gate dielectric layer 82 is typically less than 25 Å thick. In another example, the gate dielectric layer 82 may be made of nitrided silicon dioxide, or another dielectric material such as a high-k material. An upper surface of the gate dielectric layer 82 is exposed when the wafer substrate 80 is inserted into the chamber 12.

FIG. 4 illustrates the formation of a silicon germanium layer 84 directly on the exposed upper surface of the gate dielectric layer 82, according to the principles that will now be described. No seed layer is formed on the gate dielectric layer 82 before the silicon germanium layer 84 is formed.

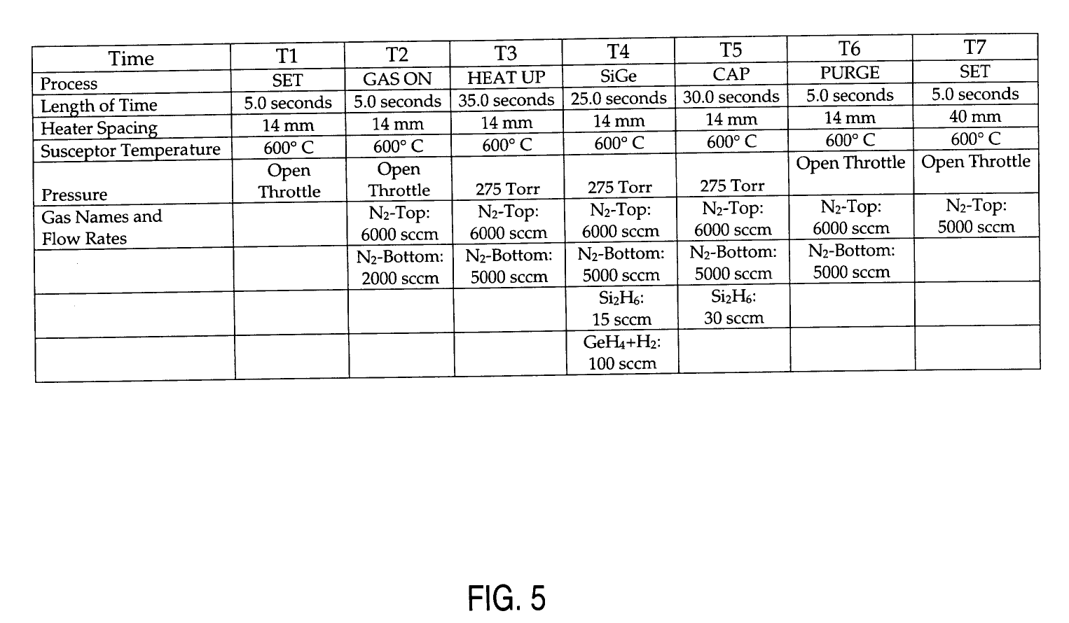

FIG. 5 illustrates the process flow for forming the silicon germanium layer after the wafer substrate 80 is located in the chamber 12.

At time T1, the susceptor 16 is heated to 600° C., and the wafer substrate 80 is positioned at approximately 14 mm from the gas dispersion plate 38 as hereinbefore described. At time T2, nitrogen gases are introduced through the inlet ports 26 and 28 while the pump is being operated. The gas flow rate of nitrogen gas in the top of the chamber 12 (i.e., through the first gas inlet port 26 above the susceptor 16) is approximately 6000 standard cubic centimeters per minute (sccm), and in the bottom of the chamber 12 (i.e., through the second gas inlet port 28 below the susceptor 16), approximately 2000 sccm. This is continued for approximately five seconds.

Beginning at time T3, the susceptor 16 is allowed to heat up while the pressure within the chamber 12 is increased to approximately 275 Torr. Nitrogen gas flow in the top of the chamber is maintained at approximately 6000 sccm, and is increased to approximately 5000 sccm in the bottom of the chamber 12. This is continued for approximately 35 seconds, whereafter the gate dielectric layer 82 is still exposed.

Beginning at time T4, with the gate dielectric layer 82 still exposed, the silicon germanium layer 84 is formed. The susceptor temperature and the pressure are maintained at 600° C. and 275 Torr, respectively. Disilane gas and diluted germaine gas simultaneously begin to flow into the chamber 12 at flow rates of 15 sccm and 100 sccm, respectively. The diluted germaine gas includes approximately 10% germaine gas and approximately 90% hydrogen gas. An advantage of using disilane gas as opposed to silane gas (SiH₄) is that disilane has similar thermal reactivity as does germaine. The disilane and germaine molecules break down at a more similar rate at a particular temperature than do silane and germaine. The similarity in reactivity between disilane and germaine results in a higher-quality, more silicon-rich film on the gate dielectric layer with better uniformity than a silane-and-germaine-based film. Although not specifically tested, it is also believed that higher-order silane gases, such as Si₃H₈, may provide benefits over silane gas, although not as good as disilane gas. Inert gases other than hydrogen gas may be used to dilute the germaine, such as nitrogen gas (N₂) or argon gas (Ar).

In the given example, the relative flow rates of the disilane gas and the undiluted germaine is approximately 1.5. In another embodiment, the ratio may be between 0.2 and 5.0.

In the given example, the percentage of the germaine is approximately 10% of the diluted germaine. In another example, the percentage may be between 0.5% and 50%.

In the given example, the susceptor 16 is heated to approximately 600° C., so that the substrate 80 is at approximately 580° C. In another example, the temperature of the susceptor 16 may be between 520° C. and 650° C.

In the given example, the pressure within the chamber is approximately 275 Torr. In another example, the pressure may be between 10 and 350 Torr, preferably between 250 Torr and 300 Torr.

In the given example, the germanium has an atomic count of 30% in the silicon germanium. In another example, the atomic count may be between 5% and 50%, or more typically, between 10% and 40%.

Silicon germanium deposition is continued for approximately 25 seconds, so that the silicon germanium layer 84 is approximately 500 Å thick. The silicon germanium layer may be between 50 and 1000 Å thick, in another example.

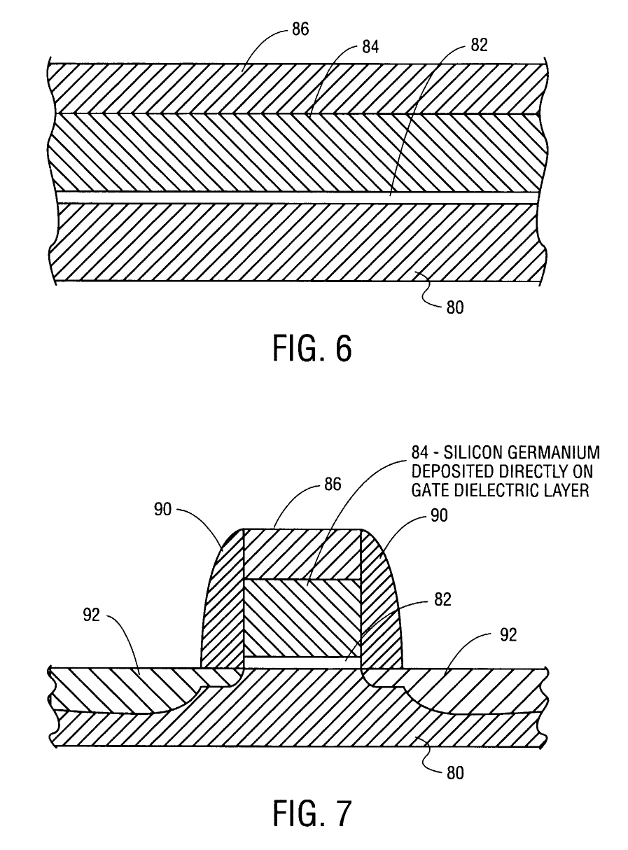

At time T5, the flow of the diluted germaine is shut off, and the disilane flow rate is increased to 30 sccm. As illustrated in FIG. 6, an amorphous silicon cap layer 86 is so formed (by the disilane gas) on top of the silicon germanium layer 84. The cap layer 86 is formed for approximately 30 seconds, and is approximately 700 Å thick, but may be between 100 and 1000 Å thick in another example.

Referring again to FIG. 5, at time T6, the flow of the disilane is shut off. The chamber 12 is then purged with nitrogen gas for approximately five seconds. At time T7, and as further illustrated in FIG. 2, the susceptor 16 is then lowered so that it is approximately 40 mm from the gas dispersion plate 38, whereafter the wafer substrate 80 is removed from the chamber 12, following a reverse order according to which it was inserted into the chamber 12.

FIG. 7 illustrates a transistor that is manufactured out of the layers illustrated in FIG. 6. The gate dielectric layer 82, silicon germanium layer 84, and cap layer 86 are masked and etched to a required width or “gate length” of the transistor. The silicon germanium layer 84 and the cap layer 86 jointly form a gate electrode of the transistor. In the case of a PMOS device, where the substrate 80 is n-doped, boron is subsequently implanted into the gate electrode so that the gate electrode is p-doped. Boron is also implanted into surfaces of the wafer substrate 80 on opposing sides of the gate electrode to form source and drain regions 92. Phosphorus or arsenic are used as impurities in an NMOS device where the substrate is p-doped. Spacers 90 are then formed next to side surfaces of the gate electrode, and more boron is implanted into the gate electrode and the wafer substrate 80.

The wafer substrate 80 is then heated to activate the boron and make the electrode conductive. The boron diffuses throughout the gate electrode. The silicon germanium layer 84, however, prevents boron diffusion through the gate dielectric layer 82 into the wafer substrate 80. Boron is prevented from entering the wafer substrate 80 and impairing the switching characteristics in a channel between the source and drain regions 92. Boron is also prevented from depleting out of a lower region of the silicon germanium layer 84, referred to as “poly depletion problems,” which increases the effective gate dielectric thickness.

The benefit of the cap layer 86, being made of 100% pure silicon, is that it can be metallized with metals such as cobalt that do not form effective suicides with silicon germanium but form effective silicides with pure silicon An effective silicide can be formed with a silicon purity of, for example, at least 95%.

An advantage of not having a seed layer between the gate dielectric layer 82 and the silicon germanium layer 84 is that the effective gate dielectric thickness is equal to the thickness of the silicon dioxide gate dielectric layer 82.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

What is claimed:

1. A semiconductor processing method, comprising:
depositing a silicon germanium layer directly on a gate dielectric layer formed over a semiconductor material of a substrate.

2. The method of claim 1, wherein the gate dielectric layer is less than 25 Å thick.

3. The method of claim 1, wherein the semiconductor material is silicon and the gate dielectric layer is made of silicon dioxide, nitrided silicon dioxide, or a high-k material.

4. The method of claim 1, wherein the silicon germanium layer is deposited by introducing a germanium-containing gas and a silicon-containing gas into a chamber in which the substrate is located, the silicon-containing gas being SiₓH₂ₓ₊₂, where x is at least 2.

5. The method of claim 4, wherein the germanium-containing gas is GeH₄.

6. The method of claim 4, wherein the germanium-containing gas is diluted before flowing into the chamber.

7. The method of claim 6, wherein the germanium-containing gas is diluted with an inert gas.

8. The method of claim 6, wherein a percentage of a combination of the germanium-containing gas and the inert gas is between 0.5% and 50%.

9. The method of claim 4, wherein x is 2.

10. The method of claim 4, wherein a ratio between the silicon-containing gas and the germanium-containing gas is between 0.2 and 5.0.

11. The method of claim 4, wherein the germanium-containing and the silicon-containing gases are diluted with N₂ gas while the silicon germanium layer is being formed.

12. The method of claim 1, wherein the substrate is heated to a temperature between 520° C. and 650° C. when the silicon germanium layer is being deposited.

13. The method of claim 1, wherein a chamber in which the substrate is located when the silicon germanium layer is deposited is at a pressure between 10 and 350 Torr.

14. The method of claim 1, wherein an atomic count of germanium in the silicon germanium layer is between 5% and 50%.

15. The method of claim 1, further comprising:
fabricating a transistor with the gate dielectric layer forming a gate dielectric layer of the transistor, and the silicon germanium layer forming at least part of a gate electrode of the transistor.

16. The method of claim 1, further comprising:
depositing a cap layer over the silicon germanium layer.

17. The method of claim 16, wherein the cap layer includes less germanium than the silicon germanium layer.

18. The method of claim 17, wherein the cap layer comprises at least 95% silicon.

19. The method of claim 16, wherein the silicon germanium layer and the cap layer are deposited insitu within one chamber.

20. The method of claim 16, further comprising:
fabricating a transistor with the gate dielectric layer forming a gate dielectric layer of the transistor, and the silicon germanium layer together with the cap jointly forming at least part of a gate electrode of the transistor.

21. A semiconductor processing method, comprising:
locating a substrate in a processing chamber;
allowing a germanium-containing gas and a silicon-containing gas into the chamber while a gate dielectric layer formed over a semiconductor material of the substrate is exposed, the gases combining to form a layer on the gate dielectric layer; and
removing the substrate from the processing chamber.

22. The method of claim 21, wherein the gate dielectric layer is less than 25 Å thick.

23. The method of claim 21, wherein the semiconductor material is silicon and the gate dielectric layer is made of silicon dioxide, nitrided silicon dioxide, or a high-k material.

24. The method of claim 21, wherein the silicon-containing gas is SiₓH₂ₓ₊₂, where x is at least 2.

25. The method of claim 21, wherein x is 2.

26. The method of claim 21, further comprising:
reducing a ratio between the germanium-containing gas and the silicon-containing gas before the substrate is removed from the chamber.

27. A semiconductor transistor, comprising:
a substrate, including a semiconductor material having one conductivity type;
a gate dielectric layer over the semiconductor material;
a gate electrode including a silicon germanium layer formed directly on the gate dielectric layer; and
source/drain regions on opposite sides of the gate electrode, having a conductivity type opposite to the conductivity type of the semiconductor material.

28. The semiconductor transistor of claim 27, wherein the gate electrode includes a cap over the silicon germanium layer, of a material different from the silicon germanium layer.

29. The semiconductor transistor of claim 28, wherein the cap includes silicon.

30. The semiconductor transistor of claim 29, wherein the cap includes at least 95% silicon.
